(19) United States
(12) Patent Application Publication
(10) Pub. No.: US 2020/0373272 A1
(43) Pub. Date: Nov. 26, 2020

(54) High-Reliability Copper Alloy Bonding Wire for Electronic Packaging and Preparation Method Therefor

(71) Applicant: South China University of Technology, Guangzhou City (CN)

(72) Inventors: Bin Yuan, Guangzhou City (CN); Zheng Luo, Guangzhou City (CN); Min Zhu, Guangzhou City (CN); Yunguan Xu, Guangzhou City (CN); Shuyao Peng, Guangzhou City (CN)

(21) Appl. No.: 16/642,971

(22) PCT Filed: Nov. 23, 2017
(86) PCT No.: PCT/CN2017/112638

§ 371 Date: Aug. 4, 2020

(30) Foreign Application Priority Data
Sep. 1, 2017 (CN) 201710779698.5

(51) Int. Cl. H01L 23/00; C22C 9/00

(52) U.S. Cl. CPC H01L 24/45; H01L 2924/01026; C22C 9/00; H01L 2224/4321; H01L 2224/4381; H01L 2224/43848; H01L 2224/45147; H01L 2224/45184; H01L 2224/45139; H01L 2224/45163; H01L 2224/45166; H01L 2224/45171; H01L 2224/4516; H01L 2924/01029; H01L 2924/01074; H01L 2924/01047; H01L 2924/01021; H01L 2924/01022; H01L 2924/01024; H01L 24/43

(57) ABSTRACT

The present invention discloses a high-reliability copper alloy bonding wire for electronic packaging and a preparation method therefor; the bonding wire comprises the following raw material components in percentage by weight: a copper content being 99.75%-99.96%, a tungsten content being 0.01-0.1%, a silver content being 0.01%-0.03%, a scandium content being 0.01%-0.02%, a titanium content being 0.001%-0.03%, a chromium content being 0.001%-0.03%, and an iron content being 0.001%-0.02%. The preparation method therefor comprises: extracting high-purity copper with a purity greater than 99.99%, preparing same as copper alloy ingots, and further preparing same as as-cast copper alloy crude bars, drawing the crude bars to form copper alloy wires, subjecting same to a heat treatment, and then precise drawing, a heat treatment, and cleaning to obtain copper alloy bonding wires of different specifications.

### TECHNICAL FIELD

The present invention relates to a copper alloy bonding wire, in particular to a high-reliability copper alloy bonding wire for electronic packaging and a preparing method thereof. The copper alloy bonding wire is used for the post-packaging process of an electronic integrated circuit (IC) and a semiconductor discrete device (such as LED).

### BACKGROUND

In modern society, with the rapid development of science and technology and electronic information technology, electronic components are used in almost all modern products, ranging from military satellites, missiles, radars, etc., as well as household automobiles, televisions, computers, washing machines, refrigerators, etc., to mobile phones, navigation devices, various magnetic cards, wearable devices, LED lighting and, etc. Most products are based on the integrated circuit (IC) and a semiconductor component. The IC and semiconductor discrete device are the development basis of electronic information products; bonding wires are still the main technical means for the connections (or wire bonding) of a chip in an IC chip with an external lead, as well as in connection methods of a semiconductor chip and an electrode in LED packings. The bonding of IC and LED wire materials is the most common, simple and effective way to realize the electrical connection of various circuits in the pre-packaged housing of circuit chips, to transmit the electrical signals of the chips and to dissipate the heat generated in the chips; therefore, the bonding wire has become one of the four important structural materials in the electronic packaging industry.

With the booming development of the microelectronics industry and the LED lighting industry, the IC packaging is rapidly moving towards the direction of a small size, a high strength, a high density, multilayer chips, and low cost, therefore, the materials for IC packaging are required to be ultra-fine (a diameter of 0.018 mm, even 0.015 mm), and have high mechanical performances (a high breaking strength and a good elongation), an excellent bonding performance and a bonding reliability; at the same time, LED packaging is also rapidly developing towards the direction of a high power, low cost, and highly dense; therefore, the package bonding wires are required to be ultra-fine, and have high performances (high conductivity and thermal conductivity), and a low price, etc.

At present, gold and silver bonding wires are widely used in the package bonding wires used in the fields of ICs, and semiconductor discrete devices, etc. Since gold and silver are precious metals, and have a high and rising price, this bringing a heavy cost pressure to users who have the maximum consumption in the middle and low-end LED and IC packaging. The traditional gold wire has gradually reached the limit in its electrical and thermal conductivities, and cannot meet the requirements for bonding technical parameters in the bonding process, such as a narrow spacing, a low radian, a long arc distance and a high power. Therefore, there is an urgent need for a new bonding wire material with relatively low cost and stable and reliable performance to replace gold and silver bonding wires in the industry.

As an inner bonding lead, a copper wire has higher electrical and thermal conductivities than that of a gold wire, which can be used to manufacture power devices with higher requirements on current loading, and enables easier heat dissipation during high-density packaging. The strong tensile strength of the copper wire can allow a wire diameter to be thinner, and the pad size and the pad spacing can also be correspondingly reduced, and the price thereof is 90% or more cheaper than that of a precious metal bonding wire material. However, the easy oxidation at a high temperature, a high hardness and easy corrosion of wire surface during resin packing of copper are the most concerned shortcomings. Therefore, a pure copper bonding wire requires more stringent bonding process parameters and a narrower process window than that of a gold wire bonding, such as the use of a protection gas (95% N₂+5% H₂) to prevent surface oxidation, a higher bonding force and ultrasonic energy, etc. during the ball formation to ensure the reliability of bonding. At present, there are two main directions for the development of copper bonding wires: surface coating and alloying of high purity copper wires.

The surface coating mainly involves plating palladium on the surface of pure copper bonding wires, the core material of the copper wires is 99.9999% copper, and the process for plating palladium is vacuum coating. The distribution and thickness of this palladium layer are very important for the reliability of copper bonding wires, which greatly increases the complexity of the preparation process; at the same time, since palladium is a noble metal and has a high price, the cost of palladium plated pure copper bonding wires is also greatly increased. In addition, the purpose of plating palladium is to isolate the copper wires from the air and reduce the oxidation rate thereof; however, since the recrystallization temperature of the palladium plating layer and the copper wires of the substrate are different, defects, such as crooked ball, are prone to happen during the ball-burning and bonding processes.

Alloying involves the formation of a uniform copper alloy by adding a trace amount of an alloying element which improves the oxidation resistance and ballability of the copper wire, reduces the hardness, increases the strength, etc., without losing the electrical and thermal conductivities of copper, and this is the main direction for the research and development of high-quality copper bonding wires at present. However, most of the currently reported copper alloy bonding wires focus on improving the oxidation resistance and strength of copper alloy bonding wires, and none of them can improve all the major disadvantages of the copper alloy bonding wires including the oxidation resistance, corrosion resistance and a high hardness. The oxidation resistance of some currently reported copper alloy bonding wires is improved and the strength thereof is high; but they have a poor plasticity, cannot be drawn into filaments continuously, and also have a poor corrosion resistance, so their bonding reliability is poor. The reason may mainly lie in that for the copper alloy bonding wires of the prior art, only adding some alloying elements to improve the oxidation resistance and strength is take into consideration, but adding some elements to improve the corrosion resistance and bonding reliability is not taken into consideration, and there is also no comprehensive consideration from the microstructure and alloy composition.

### SUMMARY OF THE INVENTION

The object of the present invention is to overcome the shortcomings of the prior art, and provide a copper alloy bonding wire for electronic packaging and a preparing method therefor, which overcomes the key problems of an easy oxidation on the surface, a poor corrosion resistance, a breakage during drawing and a poor reliability, etc. of the existing copper alloy bonding wires.

The technical solution adopted by the present invention to solve the technical problem thereof is:

a high-reliability copper alloy bonding wire for electronic packaging comprising the following raw material components in percentage by weight: a copper content being 99.75%-99.96%, a tungsten content being 0.01-0.1%, a silver content being 0.01%-0.03%, a scandium content being 0.01%-0.02%, a titanium content being 0.001%-0.03%, a chromium content being 0.001%-0.03%, an iron content being 0.001%-0.02%, and inevitable impurities; the content of S and O in the impurities being ≤10 wt. ppm in the entire copper alloy bonding wire, and the sum of the content of all elements being equal to 100%.

Preferably, the purity of copper in said raw materials is greater than 99.99%.

Preferably, the purity of any one of tungsten, silver, scandium, iron, titanium, and chromium in said raw materials is required to be greater than 99.999%.

The method for preparing the high-reliability copper alloy bonding wire for electronic packaging comprises the following steps:

1) extracting high-purity copper: after electroplating a copper material, extracting the high-purity copper with a purity greater than 99.9999%, then cleaning and drying same for later use;

2) preparing copper alloy ingots: adding tungsten, silver, scandium, iron, titanium, and chromium into the high-purity copper obtained in step 1), mixing same and then heating same under the protection of argon to prepare the copper alloy ingots;

3) continuous casting into as-cast copper alloy bars: adding the prepared copper alloy ingots into a metal horizontal continuous casting chamber protected by nitrogen, heating, melting, refining and degassing same, injecting a molten solution into a liquid storage tank for heat preservation, and completing the horizontal continuous casting of the copper alloy molten solution to obtain as-cast copper alloy bars of Φ4-Φ6 mm;

4) homogeneous annealing: subjecting the as-cast copper alloy bars of Φ4-Φ6 mm to homogeneous annealing, wherein the annealing temperature is controlled to be 600-900° C., the annealing time is 6-10 hours, the protective atmosphere is 95% N₂+5% H₂, and the protective gas is continuously introduced during the process of cooling to room temperature;

5) coarse drawing: drawing the as-cast copper alloy bars of Φ4-Φ6 mm after homogeneous annealing into copper alloy bars of Φ2-Φ3 mm, and then drawing same into copper alloy wires with a diameter of 0.5-1 mm;

6) heat treatment: subjecting the copper alloy wires with a diameter of 0.5-1 mm to intermediate annealing, wherein the annealing temperature is 400-600° C., the annealing time is 2-6 hours, and the protective atmosphere is 95% N₂+5% H₂;

7) precise drawing: subjecting the copper alloy wires after the heat treatment to precise drawing to form finished copper alloy bonding wires with a diameter of 15 μm-50 μm respectively;

8) heat treatment: subjecting the copper alloy single crystal bonding wires after the precise drawing to annealing, wherein the annealing temperature is 400-600° C., the annealing time is 0.2-0.6 seconds, and the protective atmosphere is 95% N₂±5% H₂; and

9) cleaning the surface and drying same to obtain finished copper alloy bonding wires.

Preferably, the content of impurities S and O in the high-purity copper in step 1) is less than 5 wt. ppm.

Preferably, the mixing in step 2) is mechanical mixing.

Preferably, the heating and melting in step 2) are performed in a high-purity graphite crucible, and the heating and melting are performed by electric arc furnace heating.

Preferably, the heating and melting in step 3) is performed by using intermediate frequency induction heating.

Preferably, the surface cleaning in step 9) includes washing the bonding wires with a diluted acid solution, then ultrasonically washing same, and further washing same with high-purity water.

Preferably, after the surface cleaning and drying in 9), the method further includes rewinding, winding and packaging the finished copper alloy bonding wires.

The principle of the present invention is that adding a certain amount of element tungsten (W) into copper can greatly increase the oxidation resistance, corrosion resistance and strength of copper alloys, and refine the grains when ball bonding the copper alloys into balls, and ensure the bonding strength and reliability; adding a certain amount of element silver (Ag) into copper can increase the oxidation resistance of copper alloys and ensure the electrical and thermal conductivities of copper alloys; adding a certain amount of scandium (Sc) into copper can greatly affect the structure and properties of copper alloys, which can greatly increase the strength of copper alloys, and also maintain the plasticity of the alloys, and brings excellent corrosion resistance and ballability (bonding performance). Since scandium is both a rare earth metal and a transition group metal, it has both the functions of purifying rare earth elements and improving the structure of the ingots, and the recrystallization inhibitor of transition group elements in copper alloys. The main effect of adding a small amount of titanium (Ti) to copper is to reduce the added amount of Sc, reduce the cost of the alloy, and at the same time produce a strong modification effect and inhibit recrystallization ability. Adding a small amount of chromium (Cr) to copper can increase the corrosion resistance, conductivity and strength of copper alloys. Adding a small amount of iron (Fe) to copper can further ensure the conductivity of the copper alloy, reduce the hardness, and ensure the bonding reliability of the bonding wires to different pad materials. Silver, scandium, titanium, chromium, and iron can all solid dissolve into copper to form a solid solution. However, tungsten and copper do not solid dissolve to each other, but adding titanium or chromium can form a complete solid solution with tungsten, thereby ensuring that all tungsten is solid dissolved into the copper alloy, forming a single crystal structure, and reducing the existence of grain boundaries, thereby reducing the hardness of the copper alloy, and improving electrical and thermal conductivities; adding titanium and chromium at the same time mainly reduces the addition amount of an individual element to ensure the conductivity and strength of the copper alloy. The added elements are not expensive, and can therefore reduce the cost of copper alloy bonding wires.

The comprehensive consideration of the alloy composition and microstructure of the present invention is on the basis of the added alloying elements can ensure the electrical conductivity (Ag, Fe), oxidation resistance (W, Ag) and strength (W) of the copper alloy, the trace elements which can increase its corrosion resistance (W, Cr) and bonding reliability (W, Sc, Ti, Fe) are added, and the Sc element is intentionally added at the same time to increase the plasticity of the copper alloy bonding wire; in addition, in order to ensure that the copper alloy bonding wire forms a single crystal structure, the elements Ti and Cr are intentionally added to solid dissolve the element W to obtain a single crystal copper alloy bonding wire. Since there are no grain boundaries, its hardness is reduced, and the electrical and thermal conductivities and plasticity are guaranteed.

Compared with the prior art, the present invention has the following advantages:

1) The copper alloy bonding wire for electronic packaging of the present invention has good oxidation resistance and ballability, and an excellent corrosion resistance (defective rate for permeability is less than 5%, which is 100% higher than the existing copper alloy bonding wires), a high bonding reliability (it passes all reliability tests), high electrical conductivity (minimum fusing current is 0.28 A-0.3 A, which is 20% higher than the general copper alloy bonding wire (0.23 A) or more) and thermal conductivity, a high strength (6-11.5 cN, 50% higher than the existing copper alloy bonding wires) and a good plasticity (14.6-18%, 12% higher than the existing copper alloy bonding wires or more);

2) The copper alloy bonding wire for electronic packaging of the present invention can meet the requirements of electronic packaging on high performance, multifunction, miniaturization and low cost.

### BRIEF DESCRIPTION OF THE DRAWINGS

FIG. 1 is a morphology diagram of a bonding joint when the copper alloy bonding wire of Example 1 is used for ball bonding.

### DETAILED DESCRIPTION OF EMBODIMENTS

In order to better support the present invention, the present invention will be further described with reference to the drawings in combination with the examples, but the examples of the present invention are not limited thereto.

The examples relate to the test of performance parameters. The reference standards are YS/T 678-2008 (Copper wire for bonding lead device) and GB/T 8750 (Gold bonding wire for semiconductor package). The test method for breaking force and elongation is GB/T 10573 (Tensile testing method for fine wire of non-ferrous metals). With regard to the method for testing the bonding strength, reference is made to US MIL-STD 883G test standard (Test method standard microcircuits, 2006). With regard to the reliability test, reference is made to Wire bonding quality assurance and testing methods, D. T. Ramelow and the conventional reliability test methods of the electronic packaging industry. The specific test items include flitch reflow bonding (170±5° C.-260±5° C., 7 minutes, 100 cycles), storage test (−40° C.-100° C., 1000 hours), high temperature and humidity (85° C.±5° C., 85% RH, 1000 hours), high temperature cooking (50 minutes in a pressure cooker, and then cooling for 5 minutes, refrigerate at −40° C. for 50 minutes for 1 cycle, 1000 cycles), and air tightness (red ink mixed with water=1:1, hot plate 50° C.).

### Example 1

A copper alloy bonding wire with high-purity copper as a main material. The material constituting the bonding wire is composed of the following raw materials by weight percentage: a tungsten (W) content being 0.1%, a silver (Ag) content being 0.020%, a scandium (Sc) content being 0.013%, a titanium (Ti) content being 0.03%, a chromium (Cr) content being 0.03%, an iron (Fe) content being 0.01%, and the content of S and O in the entire copper alloy bonding wire being ≤10 wt. ppm, the balance being copper and inevitable impurities, and the sum of which being equal to 100%; the purity of copper is required to be greater than 99.99%, and the purities of tungsten, silver, scandium, iron, titanium, and chromium are all required to be greater than 99.999%.

The preparation process steps and method of the copper alloy single crystal bonding wire for microelectronic packaging are as follows:

(1) extracting high-purity copper: immersing TU00 copper (99.99% copper) in an electrolyte as an anode, and immersing a high-purity copper foil in the electrolyte as a cathode; inputting a 9 V (2.5 A) direct current between the anode and the cathode, and maintain the temperature of the electrolyte not exceeding 60° C. by supplementing a fresh electrolyte; when the cathode accumulates a certain weight of high-purity copper with a purity greater than 99.9999%, replacing the high-purity copper foil in time, and then washing and drying same for later use.

(2) preparing copper alloy ingots: extracting high-purity copper with a purity of greater than 99.9999%, and the content of impurities S and O in the high-purity copper is less than 5 wt. ppm, and then adding tungsten, silver, scandium, iron, titanium and chromium; the contents of the components thereof are as follows in percentage by weight respectively: tungsten accounts for 0.1%, silver accounts for 0.02%, scandium accounts for 0.013%, titanium accounts for 0.03%, chromium accounts for 0.03%, iron accounts for 0.01%, the balance being copper and inevitable impurities, and the sum of which is equal to 100%. After mechanically mixing these metals, placing these metals in a high-purity graphite crucible, and melting same by using electric arc furnace heating under the protection of an argon gas to prepare the copper alloy ingots.

(3) continuous casting into as-cast copper alloy bars: adding the prepared copper alloy ingots into a metal horizontal continuous casting chamber protected by nitrogen and heating same to 1300° C. by using intermediate frequency induction heating, after completely melting, refining and degassing same, injecting a molten solution into a liquid storage tank in the middle of the continuous casting chamber for heat preservation, and completing the horizontal continuous casting of the copper alloy molten solution in a continuous casting chamber maintaining the flow rate of purified nitrogen at 5 L/min to obtain as-cast copper alloy bars of Φ6 mm.

(4) homogeneous annealing: subjecting the Φ6 mm as-cast copper alloy bar to homogeneous annealing; the annealing temperature is 900° C., the annealing time is 6 hours, the protective atmosphere is 95% N₂+5% H₂, and the protective gas is continuously introduced during the process of cooling to room temperature;

(5) coarse drawing: drawing the as-cast copper alloy bars of Φ6 mm after homogeneous annealing into copper alloy bars of Φ3 mm, and then drawing same into copper alloy wires with a diameter of 1 mm.

(6) heat treatment: subjecting the copper alloy wires with a diameter of 1 mm to annealing treatment; the annealing temperature is 600° C., the annealing time is 2 hours, the protective atmosphere is 95% N₂+5% H₂.

(7) precise drawing: precisely drawing the copper alloy wires after annealing treatment into copper alloy single crystal bonding wires with a diameter of 18 μm.

(8) heat treatment: subjecting the copper alloy bonding wires after the precise drawing to annealing treatment; the annealing temperature is 450° C., the annealing time is 0.3 seconds, and the protective atmosphere is 95% N₂+5% H₂. After the annealing is completed, copper alloy bonding wires for electronic packaging are obtained.

(9) surface cleaning: washing the copper alloy single crystal bonding wire for electronic packaging after annealing treatment with a diluted acid solution, then ultrasonically washing same, further washing same with high-purity water and drying same, and

(10) winding: rewinding, winding and packaging the copper alloy single crystal bonding wires for finished microelectronic packaging.

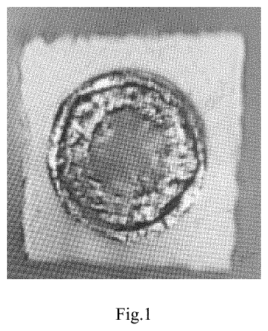

The copper alloy single crystal bonding wire has a breaking force of 5.96±0.16 cN (the standard requirement is >5 cN, which is 20% or more higher than the standard), and an elongation rate of 14.62±0.82% (the standard requirement is 4-10%, and the elongation rate is 45% or more higher than the material of the prior art), a minimum fusing current of 0.28 A (the standard requirement indicates being accepted when it is 0.23 A or more, which is increased by 20% or more), which indicates that it has a good conductivity, a high strength and a good ductility, and can be continuously drawn to 10,000 meters without breakage (the standard requirement is 5000 ms without breakage, which is 100% higher than the standard). This is mainly due to the addition of the W and Sc elements improves the strength of the bonding wire, the addition of Ag and Fe ensures the conductivity of the bonding wire, and meanwhile the addition of Sc and formation of a single crystal structure ensure its excellent ductility. After 23,000 bondings, the wire is broken only once, indicating that it has good a ductility. The copper alloy bonding wire has a moderate hardness and a good ballability by bonding; as shown in FIG. 1, it is a morphology of a bonding joint when using the copper alloy bonding wire of this Example to perform ball bonding (parameters of ball bonding: the ball forming current is 50 mA, ball forming time is 0.24 s, bonding time is 6 s, bonding power is 60-80 W, bonding pressure is 20 cN, and the protective gas is 95% N₂+5% H₂) the roundness of the bonding joint is very good without eccentricity, indicating that the oxidation resistance and ballability of the copper alloy bonding wire are good. This is mainly because the addition of the W and Cr elements improves the oxidation resistance of copper alloy bonding wires, and the addition of Ti and Cr at the same time ensures that W solid-dissolves into the copper alloy to form a single crystal solid solution structure without grain boundaries, and the hardness thereof is reduced. The test results of bonding strength are the thrust of the ball bonding joint is 18-26 g (it is required to be no less than 14 g, which is increased by more than 14%), and the tensile force is 5-10 g (it is required to be no less than 4.5 g, which is increased by more than 11%), which all meet the requirements. The reliability test items include: flitch reflow bonding test (1870 samples, test passed), storage test (1600 samples, test passed), high temperature and high humidity test (1600 samples, test passed), high temperature digestion test (100 samples, test passed), gas tightness test (100 samples, 5 permeations, defective rate 5%. A defective rate no more than 10% means that the test is passed, which is increased by 100% or more). The good bonding strength and bonding reliability are due to the addition of the W, Sc and Ti elements, which can suppress the recrystallization temperature of the ball bonding joints during ball bonding, refine the grains, greatly improve the bonding strength, and the addition of the W and Cr elements can greatly improve its corrosion resistance.

It can be seen from above that the copper alloy bonding wire of this embodiment has good oxidation resistance and ballability, a high strength, a good plasticity, an excellent corrosion resistance, a high bonding strength and a bonding reliability, and is very suitable for high-density, multi-pin and low-cost integrated circuits and LED packaging.

### Example 2

A copper alloy bonding wire with high-purity copper as a main material. The material constituting the bonding wire is composed of the following raw materials by weight percentage: tungsten (W) content being 0.05%, the silver (Ag) content being 0.025%, the scandium (Sc) content being 0.015%, the titanium (Ti) content being 0.02%, the chromium (Cr) content being 0.01%, and the iron (Fe) content being 0.015%, and the content of S and O in the entire copper alloy bonding wire being ≤10 wt. ppm, the balance being copper and inevitable impurities, and the sum of which being equal to 100%; The purity of copper is required to be greater than 99.99%, and the purities of tungsten, silver, scandium, iron, titanium, and chromium are all required to be greater than 99.999%.

The preparation process steps and method of the copper alloy single crystal bonding wire for microelectronic packaging are as follows:

(1) extracting high-purity copper: immersing TU00 copper (99.99% copper) in an electrolyte as an anode, and immersing a high-purity copper foil in the electrolyte as a cathode; inputting 8 V (3 A) direct current between the anode and the cathode, and maintain the temperature of the electrolyte not exceeding 60° C. by supplementing a fresh electrolyte. When the cathode accumulates a certain weight of high-purity copper with a purity greater than 99.9999%, replacing the high-purity copper foil in time, and then washing and drying same for later use.

(2) preparing copper alloy ingots: extracting high-purity copper with a purity of greater than 99.9999%, and the content of impurities S and O in the high-purity copper is less than 5 wt. ppm, and then adding tungsten, silver, scandium, iron, titanium and chromium; the contents of the components thereof are as follows in percentage by weight respectively: tungsten accounts for 0.05%, silver accounts for 0.025%, scandium accounts for 0.015%, titanium accounts for 0.02%, chromium accounts for 0.01%, iron accounts for 0.015%, the balance being copper and inevitable impurities, and the sum of which is equal to 100%. After mechanically mixing these metals, placing same in a high-purity graphite crucible, and melting same by using electric arc furnace heating under the protection of argon gas to prepare copper alloy ingots.

(3) continuous casting into as-cast copper alloy bars: adding the prepared copper alloy ingots into a metal horizontal continuous casting chamber protected by nitrogen and heating same to 1200° C. by using intermediate frequency induction heating, after completely melting, refining and degassing same, injecting a molten solution into a liquid storage tank in the middle of the continuous casting chamber for heat preservation, and completing the horizontal continuous casting of the copper alloy molten solution in a continuous casting chamber maintaining the flow rate of purified nitrogen at 4 L/min to obtain as-cast copper alloy bars of Φ4 mm.

(4) homogeneous annealing: subjecting the Φ4 mm as-cast copper alloy bar to homogeneous annealing; the annealing temperature is 800° C., the annealing time is 8 hours, the protective atmosphere is 95% N₂+5% H₂, and continuously introducing the protective gas during the process of cooling to room temperature;

(5) coarse drawing: drawing the as-cast copper alloy bars of Φ4 mm after homogeneous annealing into copper alloy bars of Φ2 mm, and then drawing same into copper alloy wires with a diameter of 0.5 mm.

(6) heat treatment: subjecting the copper alloy wires with a diameter of 0.5 mm to annealing treatment; the annealing temperature is 550° C., the annealing time is 4 hours, the protective atmosphere is 95% N₂+5% H₂.

(7) precise drawing: precisely drawing the copper alloy wires after annealing treatment into copper alloy single crystal bonding wires with a diameter of 20 μm.

(8) heat treatment: subjecting the copper alloy bonding wires after the precise drawing to annealing treatment; the annealing temperature is 500° C., the annealing time is 0.3 seconds, and the protective atmosphere is 95% N₂+5% H₂. After the annealing is completed, copper alloy bonding wires for electronic packaging are obtained.

(9) surface cleaning: washing the copper alloy single crystal bonding wire for electronic packaging after annealing treatment with a diluted acid solution, then ultrasonically washing same, further washing same with high-purity water and drying same, and

(10) winding: rewinding, winding and packaging the copper alloy single crystal bonding wires for finished microelectronic packaging.

The copper alloy single crystal bonding wire has a breaking force greater than 8 cN (the standard is >6 cN, which is 30% higher than the standard or more), an elongation rate greater than 15% (the standard is 6-12%, which is 25% higher than the standard or more), a minimum fusing current of 0.29 A (the standard is 0.24 A, which is 20% higher than the standard or more), has a moderate hardness and a good ballability of bonding, and is very suitable for high density and multi-pin integrated circuit packaging.

### Example 3

A copper alloy bonding wire with high-purity copper as a main material. The material constituting the bonding wire is composed of the following raw materials by weight percentage: tungsten (W) content being 0.01%, the silver (Ag) content being 0.03%, the scandium (Sc) content being 0.02%, the titanium (Ti) content being 0.001%, the chromium (Cr) content being 0.01%, and the iron (Fe) content being 0.02%, and the content of S and O in the entire copper alloy bonding wire being ≤10 wt. ppm, the balance being copper and inevitable impurities, and the sum of which being equal to 100%; The purity of copper is required to be greater than 99.99%, and the purities of tungsten, silver, scandium, iron, titanium, and chromium are all required to be greater than 99.999%.

The process steps and method for preparing the copper alloy single crystal bonding wire for microelectronic packaging are as follows:

(1) extracting high-purity copper: immersing TU00 copper (99.99% copper) in an electrolyte as an anode, and immersing a high-purity copper foil in the electrolyte as a cathode; inputting 7 V (3.5 A) direct current between the anode and the cathode, and maintain the temperature of the electrolyte not exceeding 60° C. by supplementing a fresh electrolyte. When the cathode accumulates a certain weight of high-purity copper with a purity greater than 99.9999%, replacing the high-purity copper foil in time, and then washing and drying same for later use.

(2) preparing copper alloy ingots: extracting high-purity copper with a purity of greater than 99.9999%, and the content of impurities S and O in the high-purity copper is less than 5 wt. ppm, and then adding tungsten, silver, scandium, iron, titanium and chromium; The contents of the components thereof are as follows in percentage by weight respectively: tungsten accounts for 0.01%, silver accounts for 0.03%, scandium accounts for 0.02%, titanium accounts for 0.001%, chromium accounts for 0.01%, iron accounts for 0.02%, the balance being copper and inevitable impurities, and the sum of which is equal to 100%. After mechanically mixing these metals, placing same in a high-purity graphite crucible, and melting same by using electric arc furnace heating under the protection of argon gas to prepare copper alloy ingots.

(3) continuous casting into as-cast copper alloy bars: adding the prepared copper alloy ingots into a metal horizontal continuous casting chamber protected by nitrogen and heating same to 1130° C. by using intermediate frequency induction heating, after completely melting, refining and degassing same, injecting a molten solution into a liquid storage tank in the middle of the continuous casting chamber for heat preservation, and completing the horizontal continuous casting of the copper alloy molten solution in a continuous casting chamber maintaining the flow rate of purified nitrogen at 3 L/min to obtain as-cast copper alloy bars of Φ5 mm.

(4) homogeneous annealing: subjecting the Φ5 mm as-cast copper alloy bar to homogeneous annealing; the annealing temperature is 750° C., the annealing time is 10 hours, the protective atmosphere is 95% N₂+5% H₂, and continuously introducing the protective gas during the process of cooling to room temperature.

(5) coarse drawing: drawing the as-cast copper alloy bars of 15 mm after homogeneous annealing into copper alloy bars of Φ3 mm, and then drawing same into copper alloy wires with a diameter of 1 mm.

(6) heat treatment: subjecting the copper alloy wires with a diameter of 1 mm to annealing treatment; the annealing temperature is 500° C., the annealing time is 6 hours, and the protective atmosphere is 95% N₂+5% H₂.

(7) precise drawing: precisely drawing the copper alloy wires after annealing treatment into copper alloy single crystal bonding wires with a diameter of 25 μm.

(8) heat treatment: subjecting the copper alloy bonding wires after the precise drawing to annealing treatment; the annealing temperature is 450° C., the annealing time is 0.6 seconds, and the protective atmosphere is 95% N₂+5% H₂. After the annealing is completed, copper alloy bonding wires for electronic packaging are obtained.

(9) surface cleaning: washing the copper alloy single crystal bonding wire for electronic packaging after annealing treatment with a diluted acid solution, then ultrasonically washing same, further washing same with high-purity water and drying same, and

(10) winding: rewinding, winding and packaging the copper alloy single crystal bonding wires for finished microelectronic packaging.

The copper alloy single crystal bonding wire has a breaking force greater than 11.5 cN (the standard is >8 cN, which is 30% higher than the standard or more), an elongation rate greater than 18% (the standard is 8-16%, which is 12% higher than the standard or more), a minimum fusing current of 0.3 A (the standard is 0.26 A, which is 7% higher than the standard or more), has a moderate hardness and a good ballability of bonding, and is very suitable for high density and multi-pin integrated circuit packaging.

1. A high-reliability copper alloy bonding wire for electronic packaging, wherein it comprises the following raw material components in percentage by weight: a copper content being 99.75%-99.96%, a tungsten content being 0.01-0.1%, a silver content being 0.01%-0.03%, a scandium content being 0.01%-0.02%, a titanium content being 0.001%-0.03%, a chromium content being 0.001%-0.03%, an iron content being 0.001%-0.02%, and inevitable impurities; the content of S and O in the impurities being ≤10 wt. ppm in the entire copper alloy bonding wire, and the sum of the content of all elements being equal to 100%.

2. The high-reliability copper alloy bonding wire for electronic packaging according to claim 1, wherein the purity of copper in the raw materials is greater than 99.99%.

3. The high-reliability copper alloy bonding wire for electronic packaging according to claim 1, wherein the purity of any one of tungsten, silver, scandium, iron, titanium, and chromium in the raw materials is required to be greater than 99.999%.

4. A method for preparing the high-reliability copper alloy bonding wire for electronic packaging according to claim 1, wherein it comprises the following steps:
1) extracting high-purity copper: after electroplating a copper material, extracting the high-purity copper with a purity greater than 99.9999%, then cleaning and drying same for later use;
2) preparing copper alloy ingots: adding tungsten, silver, scandium, iron, titanium, and chromium into the high-purity copper obtained in step 1), mixing same and then heating same under the protection of argon to prepare the copper alloy ingots;
3) continuous casting into as-cast copper alloy bars: adding the prepared copper alloy ingots into a metal horizontal continuous casting chamber protected by nitrogen, heating, melting, refining and degassing same, injecting a molten solution into a liquid storage tank for heat preservation, and completing the horizontal continuous casting of the copper alloy molten solution to obtain as-cast copper alloy bars of Φ4-Φ6 mm;
4) homogeneous annealing: subjecting the as-cast copper alloy bars of Φ4-Φ6 mm to homogeneous annealing, wherein the annealing temperature is controlled to be 600-900° C., the annealing time is 6-10 hours, the protective atmosphere is 95% N₂+5% H₂, and the protective gas is continuously introduced during the process of cooling to room temperature;
5) coarse drawing: drawing the as-cast copper alloy bars of Φ4-Φ6 mm after homogeneous annealing into copper alloy bars of Φ2-Φ3 mm, and then drawing same into copper alloy wires with a diameter of 0.5-1 mm;
6) heat treatment: subjecting the copper alloy wires with a diameter of 0.5-1 mm to intermediate annealing, wherein the annealing temperature is 400-600° C., the annealing time is 2-6 hours, and the protective atmosphere is 95% N₂+5% H₂;
7) precise drawing: subjecting the copper alloy wires after the heat treatment to precise drawing to from finished copper alloy bonding wires with a diameter of 15 μm-50 μm respectively;
8) heat treatment: subjecting the copper alloy single crystal bonding wires after the precise drawing to annealing, wherein the annealing temperature is 400-600° C., the annealing time is 0.2-0.6 seconds, and the protective atmosphere is 95% N₂+5% H₂; and
9) cleaning the surface and drying same to obtain finished copper alloy bonding wires.

5. The method for preparing the high-reliability copper alloy bonding wire for electronic packaging according to claim 4, wherein the content of impurities S and O in the high-purity copper in step 1) is less than 5 wt. ppm.

6. The method for preparing the high-reliability copper alloy bonding wire for electronic packaging according to claim 4, wherein the mixing in step 2) is mechanical mixing.

7. The method for preparing the high-reliability copper alloy bonding wire for electronic packaging according to claim 4, wherein the heating and melting in step 2) are performed in a high-purity graphite crucible, and the heating and melting are performed by electric arc furnace heating.

8. The method for preparing the high-reliability copper alloy bonding wire for electronic packaging according to claim 4, wherein the heating and melting in step 3) is performed by using intermediate frequency induction heating.

9. The method for preparing the high-reliability copper alloy bonding wire for electronic packaging according to claim 4, wherein the surface cleaning in step 9) includes washing the bonding wires with a diluted acid solution, then ultrasonically washing same, and further washing same with high-purity water.

10. The method for preparing the high-reliability copper alloy bonding wire for electronic packaging according to claim 4, wherein the surface cleaning and drying in step 9) also includes rewinding, winding and packaging the finished copper alloy bonding wire.
